(19) United States
(12) Patent Application Publication
(10) Pub. No.: US 2014/0157593 A1
(43) Pub. Date: Jun. 12, 2014

(54) METHOD OF MAKING HYBRID WIRING BOARD WITH BUILT-IN STOPPER, INTERPOSER AND BUILD-UP CIRCUITRY

(71) Applicant: BRIDGE SEMICONDUCTOR CORPORATION, Taipei City (TW)

(72) Inventors: Charles W.C. LIN, Singapore (SG); Chia Chung WANG, Hsinchu (TW)

(73) Assignee: BRIDGE SEMICONDUCTOR CORPORATION, Taipei City (TW)

(21) Appl. No.: 13/753,625

(22) Filed: Jan. 30, 2013

Related U.S. Application Data
(63) Continuation-in-part of application No. 13/615,819, filed on Sep. 14, 2012.
(60) Provisional application No. 61/682,801, filed on Aug. 14, 2012.
(60) Provisional application No. 61/682,801, filed on Aug. 14, 2012.

(51) Int. Cl. H05K 3/30

(52) U.S. Cl. CPC H05K 3/30
USPC 29/832

(57) ABSTRACT

The present invention relates to a method of making a hybrid wiring board with built-in stopper and interposer. In accordance with one preferred embodiment of the present invention, the method includes: forming a stopper on a dielectric layer; mounting an interposer on the dielectric layer using the stopper as a placement guide for the interposer; attaching a stiffener to the dielectric layer; and forming a build-up circuitry that covers the interposer, the stopper and the stiffener and provides signal routing for the interposer. Accordingly, the stopper can accurately confine the placement location of the interposer and avoid the electrical connection failure between the interposer and the build-up circuitry.

### CROSS REFERENCE TO RELATED APPLICATION

This application is a continuation-in-part of U.S. application Ser. No. 13/615,819, entitled “HYBRID WIRING BOARD WITH BUILT-IN STOPPER, INTERPOSER AND BUILD-UCIRCUITRY” filed Sep. 14, 2012. This application and U.S. application Ser. No. 13/615,819 claim the benefit of filing date of U.S. Provisional Application Ser. No. 61/682,801, entitled “STRUCTURE AND MANUFACTURE OF SEMICONDUCTOR ASSEMBLY AND 3D STACKING THEREOF” filed Aug. 14, 2012 under 35 USC §119(e)(1).

### BACKGROUND OF THE INVENTION

1. Field of the Invention

The present invention relates to a method of making a hybrid wiring board, and more particularly to a method of making a hybrid wiring board with built-in stopper and interposer.

2. Description of Related Art

Conventional flip-chip package includes a semiconductor die that is flipped and bonded to a laminate substrate through an array of solder bumps. The matching contact pads of the laminate substrate typically have a finer pitch than that of the backside contact pads so that the laminate substrate can accommodate high I/O chip and allow the assembled package easily attaches to a printed circuit board for next level assembly. To meet even finer feature and higher performance requirements, modern semiconductor chip incorporates a low-k dielectric as the interlayer material. As low-k dielectric material is porous, fragile and very sensitive to the interfacial stresses, conventional flip chip packages encounter various reliability and yield loss issues due to CTE mismatch between the low-k die and the laminate substrate. Therefore, incorporating a through-via interposer which has a similar CTE to that of the low-k die as a buffer is desirable to resolve the manufacturing yield and reliability concerns.

Various through-via interposers such as silicon, glass or ceramic which have similar CTE to that of the silicon are suitable for this purpose. The through-via interposer can be attached to a laminate substrate by solder bumps or it can be embedded in a build-up circuitry to form a hybrid wiring board so that the overall electrical performance can be further improved. However, as the hybrid wiring board is a non-symmetrical structure and the interposer has a different CTE to that of the build-up circuitry, a warp of the hybrid wiring board can easily occur and this will result in a not mountable interposer for low-k semiconductor chip. Furthermore, as the interposer needs to be mounted on the circuitry first before forming a highly precise conductive via for interconnection, it is impossible to align the contact pad with a laser beam if the interposer placement accuracy is not secured or if the die attach adhesive underneath the interposer “reflow” during the adhesive curing stage. As a result, a deterioration of yield or reliability might be caused.

### SUMMARY OF THE INVENTION

The present invention has been developed in view of such a situation, and an object thereof is to provide a hybrid wiring board in which an interposer is affixed on a build-up circuitry for an interconnecting chip and the build-up circuitry, warp and bend of the interposer can be suppressed, and electrical connection between the interposer to the build-up circuitry can be securely retained by conductive via.

In one preferred embodiment, the present invention provides a method of making a hybrid wiring board that includes an interposer, a stopper, a stiffener and build-up circuitry. The method of making a hybrid wiring board can include: forming a stopper on a dielectric layer; mounting an interposer on the dielectric layer using the stopper as a placement guide for the interposer that includes a first contact pad and a second contact pad on two opposite surfaces thereof, wherein the first contact pad faces a first vertical direction and is attached to the dielectric layer, the second contact pad faces a second vertical direction opposite the first vertical direction, and the stopper is located in close proximity to and laterally aligned with and laterally extends beyond peripheral edges of the interposer in lateral directions orthogonal to the vertical directions; attaching a stiffener to the dielectric layer, including aligning the interposer and the stopper within an aperture of the stiffener; and forming a build-up circuitry that covers the stopper, the interposer and the stiffener in the first vertical direction and includes a first conductive via that directly contacts the first contact pad of the interposer to provide an electrical connection between the interposer and the build-up circuitry.

In another preferred embodiment, the present invention provides another method of making a hybrid wiring board, which includes: forming a stopper on a dielectric layer; mounting an interposer on the dielectric layer using the stopper as a placement guide for the interposer that includes a first contact pad and a second contact pad on two opposite surfaces thereof, wherein the first contact pad faces a first vertical direction and is attached to the dielectric layer, the second contact pad faces a second vertical direction opposite the first vertical direction, and the stopper is located in close proximity to and laterally aligned with and laterally extends beyond peripheral edges of the interposer in lateral directions orthogonal to the vertical directions; providing a protective film that covers the interposer, the stopper and the dielectric layer in the second vertical direction; forming a build-up circuitry that covers the stopper, the interposer and the protective film in the first vertical direction and includes a first conductive via that directly contacts the first contact pad of the interposer to provide an electrical connection between the interposer and the build-up circuitry; removing the protective film; and attaching a stiffener to the dielectric layer, including aligning the interposer and the stopper within an aperture of the stiffener.

Forming the stopper on the dielectric layer can include: providing a laminate substrate that includes a metal layer and the dielectric layer; and then removing a selected portion of the metal layer to form the stopper. Alternatively, forming the stopper on the dielectric layer can include: providing a laminate substrate that includes a metal layer and the dielectric layer; then removing a selected portion of the metal layer to form a recessed portion; then depositing a plastic material into the recessed portion as the stopper; and then removing a remaining portion of the metal layer. Accordingly, the stopper can be made of a metal, a photosensitive plastic material or non-photosensitive material. For instance, the stopper can consist essentially of copper, aluminum, nickel, iron, tin or their alloys. The stopper can also consist of epoxy or polyimide.

The method of making a hybrid wiring board according to the present invention can further include: forming a placement guide on the dielectric layer. Accordingly, attaching the stiffener to the dielectric layer can include: aligning the interposer and the stopper within the aperture of the stiffener with the placement guide being in close proximity to and laterally aligned with and laterally extending beyond the outer peripheral edges of the stiffener in lateral directions.

Forming the stopper and the placement guide on the dielectric layer can include: providing a laminate substrate that includes a metal layer and the dielectric layer; and then removing a selected portion of the metal layer to form the stopper and the placement guide. Alternatively, forming the stopper and the placement guide on the dielectric layer can include: providing a laminate substrate that includes a metal layer and the dielectric layer; then removing a selected portion of the metal layer to form a recessed portion; then depositing a plastic material into the recessed portion as the stopper and the placement guide; and then removing a remaining portion of the metal layer. Accordingly, like the stopper, the placement guide for the stiffener can be made of a metal, a photosensitive plastic material or non-photosensitive material, such as copper, aluminum, nickel, iron, tin, alloys, epoxy or polyimide.

The laminate substrate can optionally further include a support plate, and the dielectric layer can be sandwiched between the metal layer and the support plate. Optionally, the method of making a hybrid wiring board according to the present invention can further include: removing the support plate or thinning the support plate after mounting the interposer and attaching the stiffener.

The interposer, which includes one or more first contact pads and optionally one or more thermal pads on the first surface and one or more second contact pads on the second surface, can be attached to the dielectric layer using an adhesive that contacts and is sandwiched between the interposer and the dielectric layer. Likewise, the stiffener can be attached to the dielectric layer using an adhesive that contacts and is sandwiched between the stiffener and the dielectric layer. In any case, the stopper and the placement guide extend from the dielectric layer in the second vertical direction, and the adhesive can contact and be coplanar with the stopper and the placement guide in the first vertical direction and lower than the stopper and the placement guide in the second vertical direction. As a result, the interposer and the stiffener can be affixed and mechanically connected to the build-up circuitry at predetermined location defined by the stopper and the placement guide that extend from the first insulating layer of the build-up circuitry and respectively extend beyond the first surface of the interposer and the attached surface of the stiffener in the second vertical direction. As the adhesive is lower than the stopper and the placement guide in the second vertical direction, the stopper and the placement guide can stop the undesirable movement of the interposer and the stiffener during curing the adhesive that contacts and is sandwiched between the first surface of the interposer and the build-up circuitry and between the stiffener and the build-up circuitry.

The build-up circuitry can include a first insulating layer, one or more first via openings and one or more first conductive traces. For instance, the first insulating layer covers the interposer, the stopper and the stiffener in the first vertical direction and can extend to peripheral edges of the hybrid wiring board, and the first conductive traces extend from the first insulating layer in the first vertical direction. As a result, forming the build-up circuitry can include: providing a first insulating layer that includes the dielectric layer and covers the stopper, the interposer and the stiffener/protective film in the first vertical direction; then forming one or more first via openings that extend through the first insulating layer and are aligned with one or more first contact pads of the interposer and optionally one or more additional first via openings that extend through the first insulating layer and are aligned with the stiffener or/and the thermal pad of the interposer; and then forming one or more first conductive traces that extend from the first insulating layer in the first vertical direction and extend laterally on the first insulating layer and extend through the first via openings and optionally the additional first via openings in the second vertical direction to form one or more first conductive vias in direct contact with the first contact pads of the interposer and optionally one or more additional first conductive vias in direct contact with the stiffener or/and the thermal pad of the interposer. Accordingly, the first conductive traces can directly contact the first contact pads to provide signal routing for the interposer, and thus the electrical connection between the interposer and the build-up circuitry can be devoid of solder. Besides, the first conductive traces can directly contact the thermal pad of the interposer to provide thermal dissipation pathway for the interposer. The first conductive traces can also directly contact the stiffener for grounding or electrical connections to passive components such as thin film resistors or capacitors deposited thereon.

The build-up circuitry can further include additional insulating layers, additional via openings, and additional conductive traces if needed for further signal routing. For instance, the build-up circuitry can further include a second insulating layer, one or more second via openings and one or more second conductive traces. The second insulating layer can extend from the first insulating layer and the first conductive trace in the first vertical direction and can extend to peripheral edges of the hybrid wiring board, and the second conductive traces extend from the second insulating layer in the first vertical direction. As a result, forming the build-up circuitry can further include: providing a second insulating layer on the first insulating layer and the first conductive trace that extends from the first insulating layer and the first conductive trace in the first vertical direction; then forming one or more second via openings that extend through the second insulating layer and are aligned with the first conductive trace; and then forming one or more second conductive traces that extend from the second insulating layer in the first vertical direction and extend laterally on the second insulating layer and extend through the second via openings in the second vertical direction to form one or more second conductive vias in direct contact with the first conductive traces, thereby electrically connecting the first conductive trace to the second conductive traces. The first via openings and the second via openings can have the same size, and the first insulating layer, the first conductive traces, the second insulating layer and the second conductive traces can have flat elongated surfaces that face in the first vertical direction.

The outmost conductive traces of the build-up circuitry can respectively include one or more interconnect pads to provide electrical contacts for the next level assembly or another electronic device such as a semiconductor chip, a plastic package or another semiconductor assembly. The interconnect pads can include an exposed contact surface that faces in the first vertical direction. As a result, the next level assembly or another electronic device can be electrically connected to the built-in interposer using a wide variety of connection media including wire bonding or solder bumps as the electrical contacts. As the electrical contacts (i.e. the second contact pads of the interposer and the interconnect pads of the build-up circuitry) can be electrically connected to one another and located on opposite surfaces that face in opposite vertical directions, the wiring board can be used for a three-dimensional semiconductor assembly. Besides, the build-up circuitry may include a thermal paddle that extends from the insulating layer of the build-up circuitry and is thermally connected to the thermal pad of the interposer through conductive vias, thereby enhancing thermal performance. For instance, the thermal paddle can extend from the first insulating layer in the first vertical direction and be thermally connected to the thermal pad of the interposer through first conductive vias.

The insulating layers can be deposited and extend to peripheral edges of the wiring board by numerous techniques including film lamination, roll coating, spin coating and spray-on deposition. The via openings can be formed through the insulating layers by numerous techniques including laser drilling, plasma etching and photolithography. The conductive traces can be formed by depositing a plated layer that covers the insulating layer in the first vertical direction and extends through the via opening to the contact pad and optionally to the stiffener, and then removing selected portions of the plated layer using an etch mask that defines the conductive trace. The plated layers can be deposited by numerous techniques including electroplating, electroless plating, evaporating, sputtering, and their combinations as a single layer or multiple layers. The plated layers can be patterned by numerous techniques including wet etching, electro-chemical etching, laser-assist etching, and their combinations to define the conductive traces.

By the above-mentioned method, the present invention can provide a hybrid wiring board that includes: an interposer that includes a first contact pad and a second contact pad on two opposite surfaces thereof, wherein the first contact pad faces a first vertical direction and the second contact pad faces a second vertical direction opposite the first vertical direction; a stopper that serves as a placement guide for the interposer and is in close proximity to and laterally aligned with and laterally extends beyond peripheral edges of the interposer in lateral directions orthogonal to the vertical directions; a stiffener that includes an aperture with the interposer and the stopper extending thereinto; and a build-up circuitry that covers the stopper, the interposer and the stiffener in the first vertical direction and includes a first insulating layer, a first via opening and a first conductive trace, wherein the first via opening in the first dielectric layer is aligned with the first contact pad of the interposer, and the first conductive trace extends from the first dielectric layer in the first vertical direction and extends through the first via opening in the second vertical direction and directly contacts the first contact pad. Optionally, the wiring board can further include: a placement guide that is in close proximity to and laterally aligned with and laterally extends beyond the outer peripheral edges of the stiffener in lateral directions orthogonal to the vertical directions.

The stopper and the placement guide can have patterns against undesirable movement of the interposer and the stiffener, respectively. For instance, the stopper and the placement guide can include a continuous or discontinuous strip or an array of posts. The stopper and the placement guide can be simultaneously formed and have the same or different patterns. Specifically, the stopper can be laterally aligned with four lateral surfaces of the interposer to stop the lateral displacement of the interposer. For instance, the stopper can be aligned along and conform to four sides, two diagonal corners or four corners of the interposer and a gap in between the interposer and the stopper preferably is in a range of about 0.001 to 1 mm. The interposer can be spaced from the inner wall of the aperture by the stopper. Moreover, the stopper can also be in close proximity to and laterally aligned with the inner wall of the aperture to stop the lateral displacement of the stiffener. Likewise, the placement guide can be laterally aligned with four outer lateral surfaces of the stiffener to stop the lateral displacement of the stiffener. For instance, the placement guide can be aligned along and conform to four outer sides, two outer diagonal corners or four outer corners of the stiffener and a gap in between the outer peripheral edges of the stiffener and the placement guide preferably is in a range of about 0.001 to 1 mm. Besides, the stopper and the placement guide preferably have a thickness in a range of 10-200 microns.

The stiffener can extend to peripheral edges of the wiring board and provide mechanical support to suppress warp and bend of the interposer. Moreover, the stiffener also can provide ground/power plane and heat sink for the build-up circuitry. The stiffener can be a single layer structure or a multi-layer structure (such as a circuit board or a multi-layer ceramic board or a laminate of a substrate and a conductive layer). For instance, the stiffener can be made of ceramics, metal or other various inorganic materials, such as aluminum oxide (Al₂O₃), aluminum nitride (AlN), silicon nitride (SiN), silicon (Si), glass, copper (Cu), aluminum (Al), stainless steel, etc. The stiffener can also be made of organic materials such as laminated epoxy, polyimde or copper-clad laminate.

The interposer can be located within the aperture or extend within and outside the aperture at a predetermined location that is defined by the stopper. In any case, the interposer and the stopper extend into the aperture, and the stopper is in close proximity to and is laterally aligned with and laterally extends beyond peripheral edges of the interposer in the lateral direction to prevent the interposer from undesirable movement. Besides, the interposer can further include one or more connecting elements (such as through vias) that electrically connect the first contact pads that face the first vertical direction and the second contact pads that face the second vertical direction and exposed from the aperture. For instance, the interposer can be a silicon, glass or ceramic interposer.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The stiffener can provide a power/ground plane, a heat sink and a robust mechanical support for the interposer and the build-up circuitry. The stopper can accurately confine the placement location of the interposer and avoid the electrical connection failure between the interposer and the build-up circuitry resulted from the lateral displacement of the interposer, thereby improving the manufacturing yield greatly. The direct electrical connection without solder between the interposer and the build-up circuitry is advantageous to high I/O and high performance. The wiring board made by this method is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional views showing a method of forming a stopper on a dielectric layer in accordance with an embodiment of the present invention;

FIG. 2A is a top view corresponding to FIG. 2;

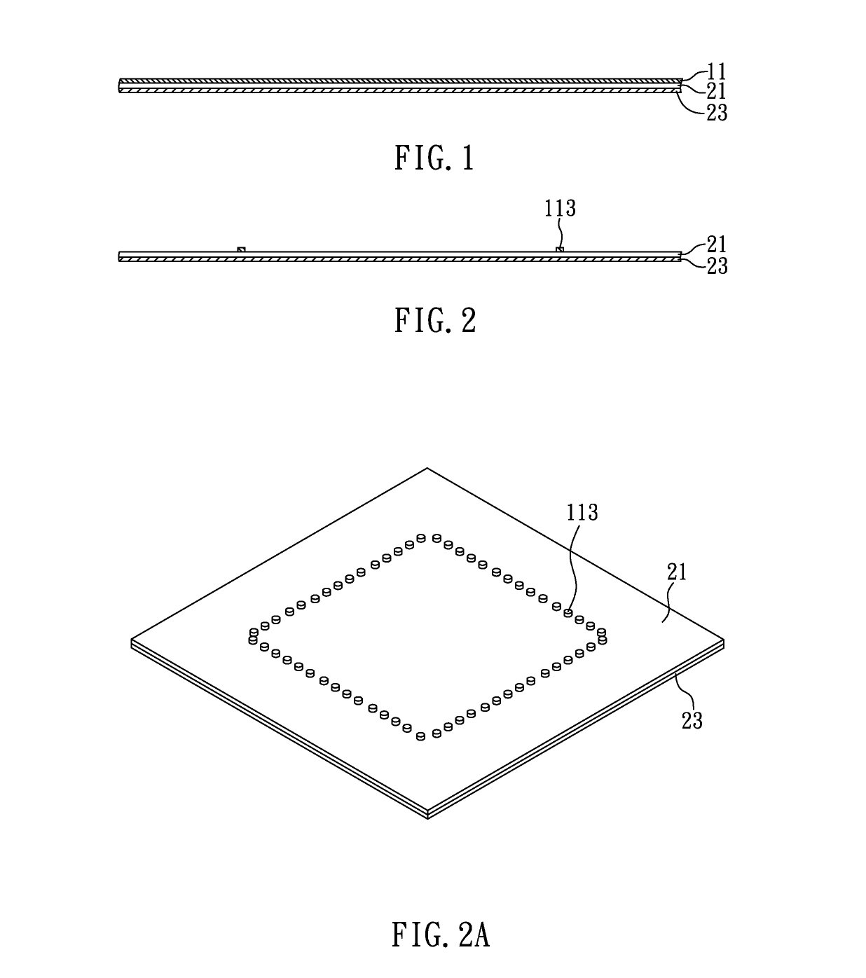

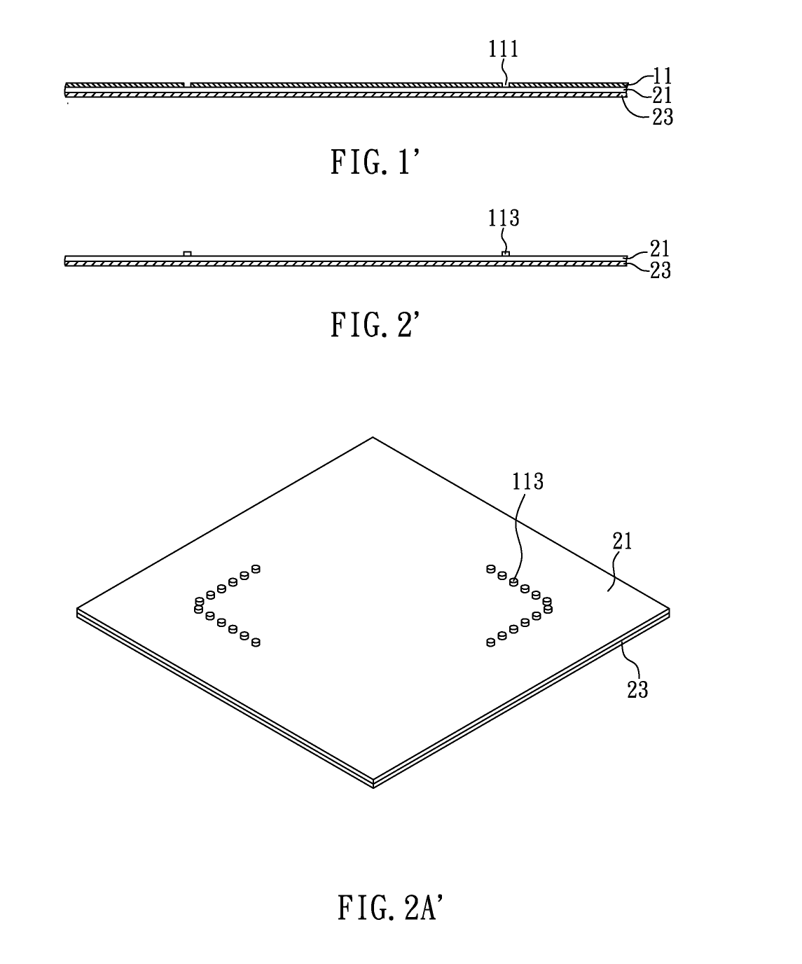

FIGS. 1′ and 2′ are cross-sectional views showing an alternative method of forming a stopper on a dielectric layer in accordance with an embodiment of the present invention;

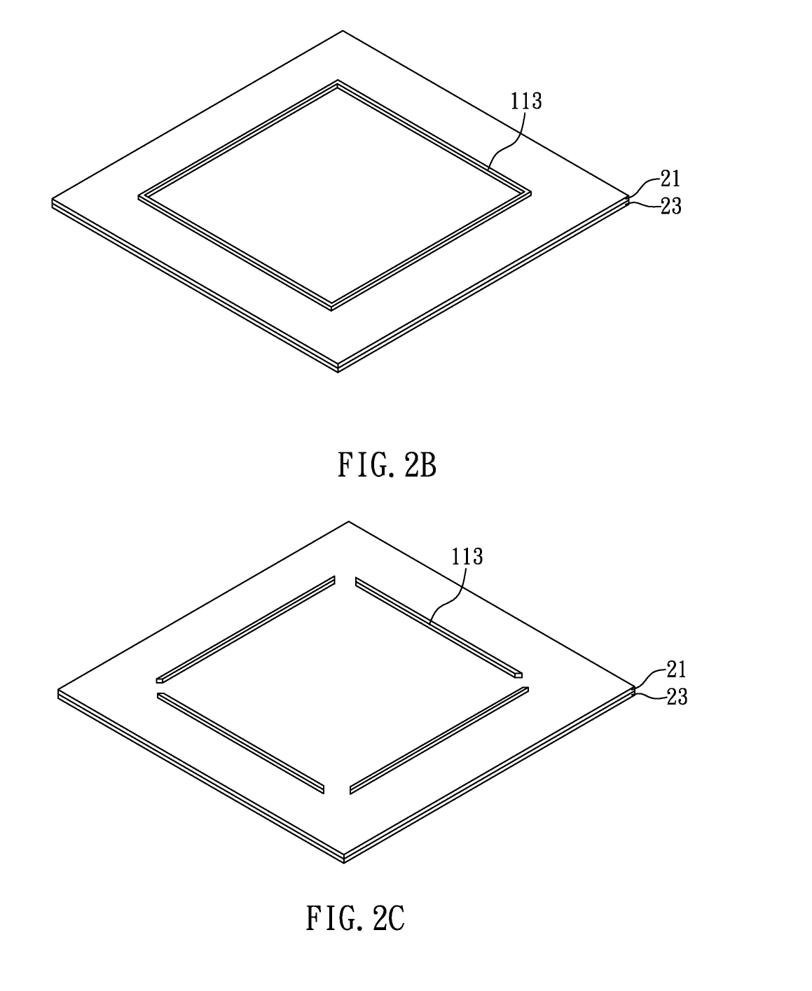

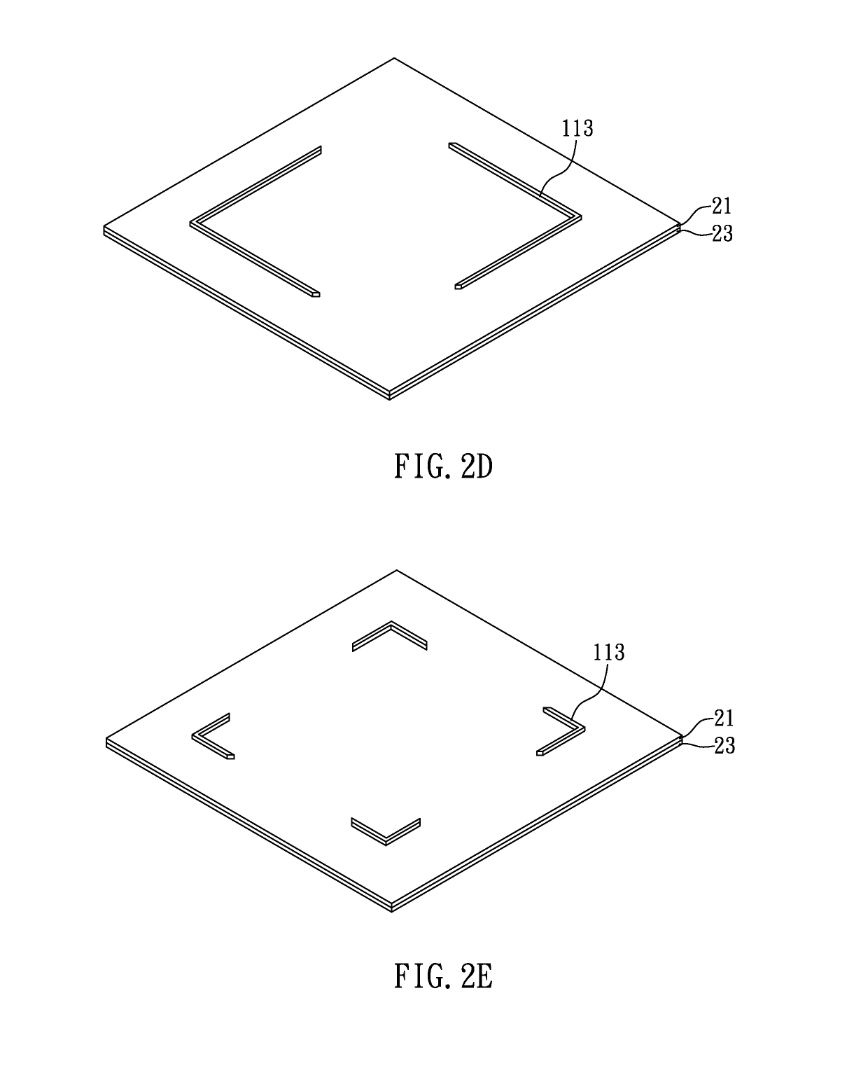

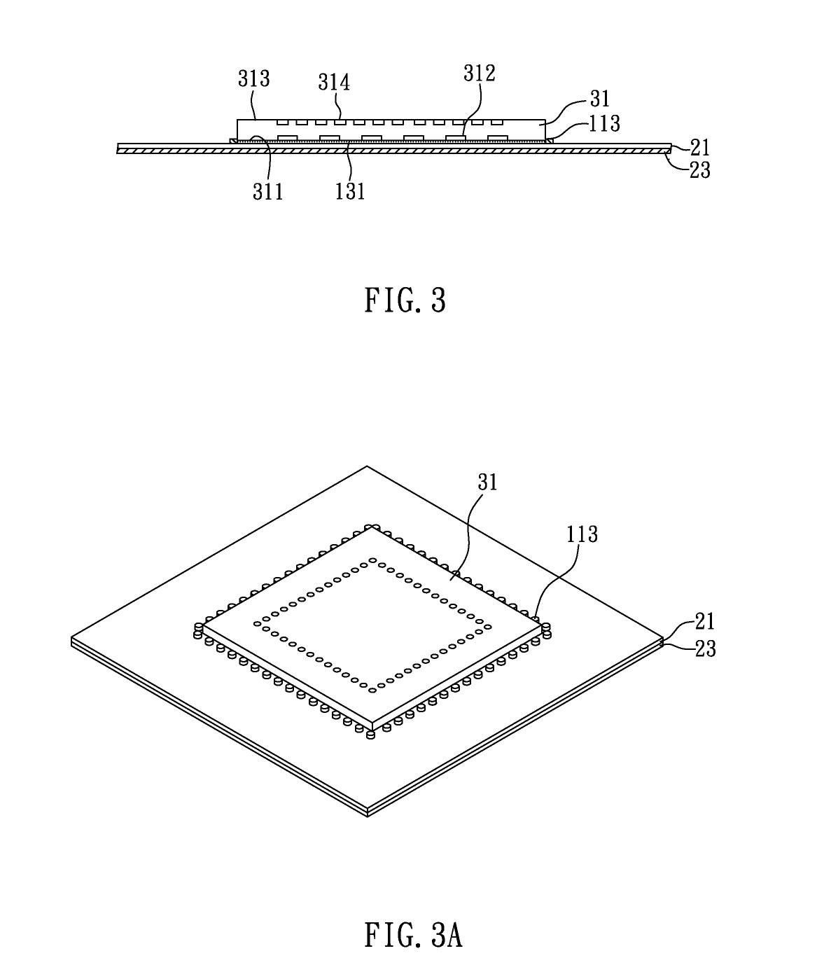

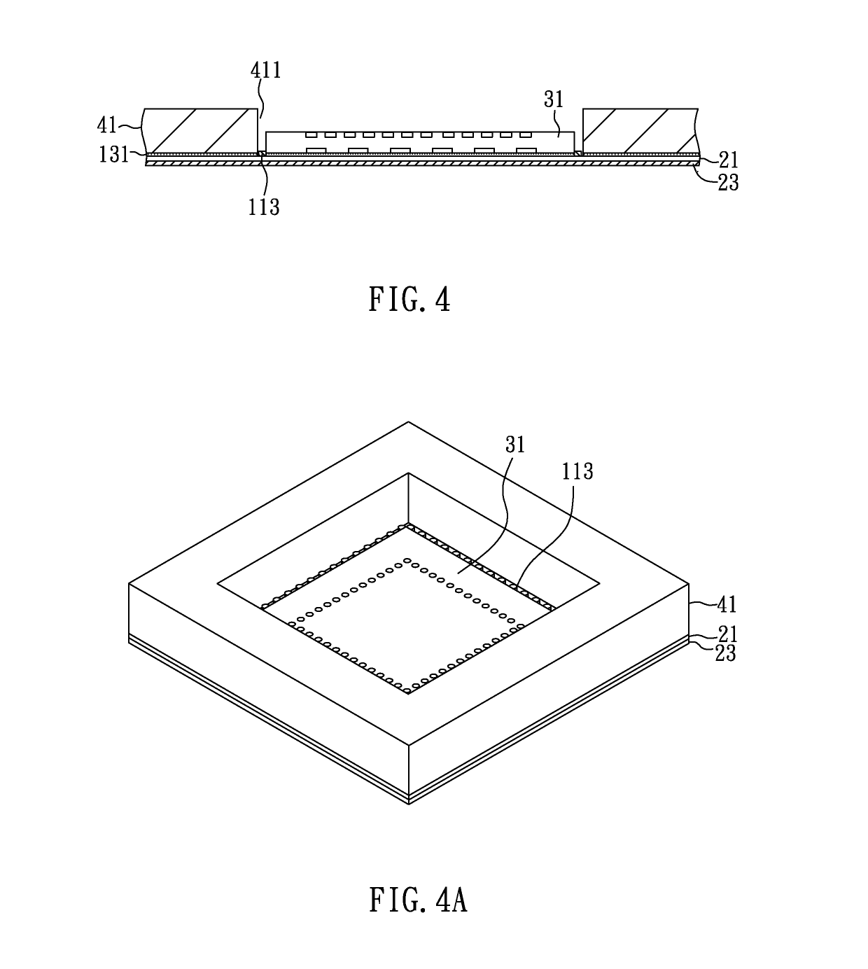

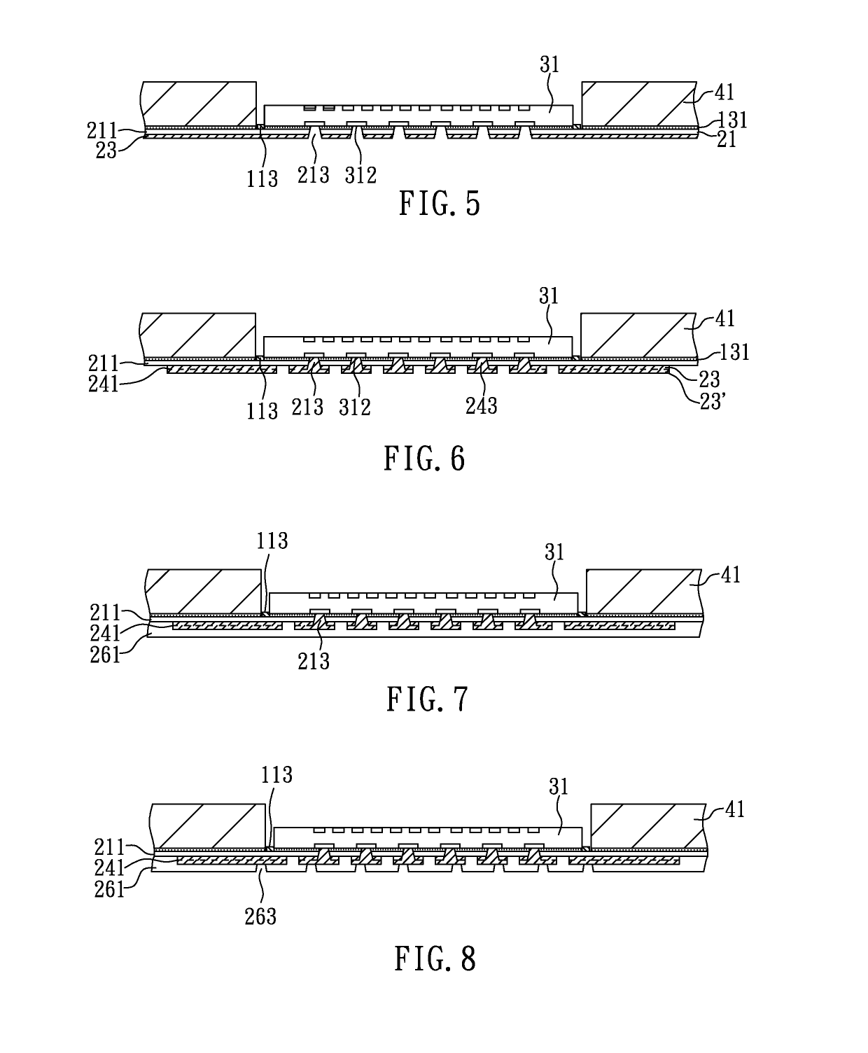

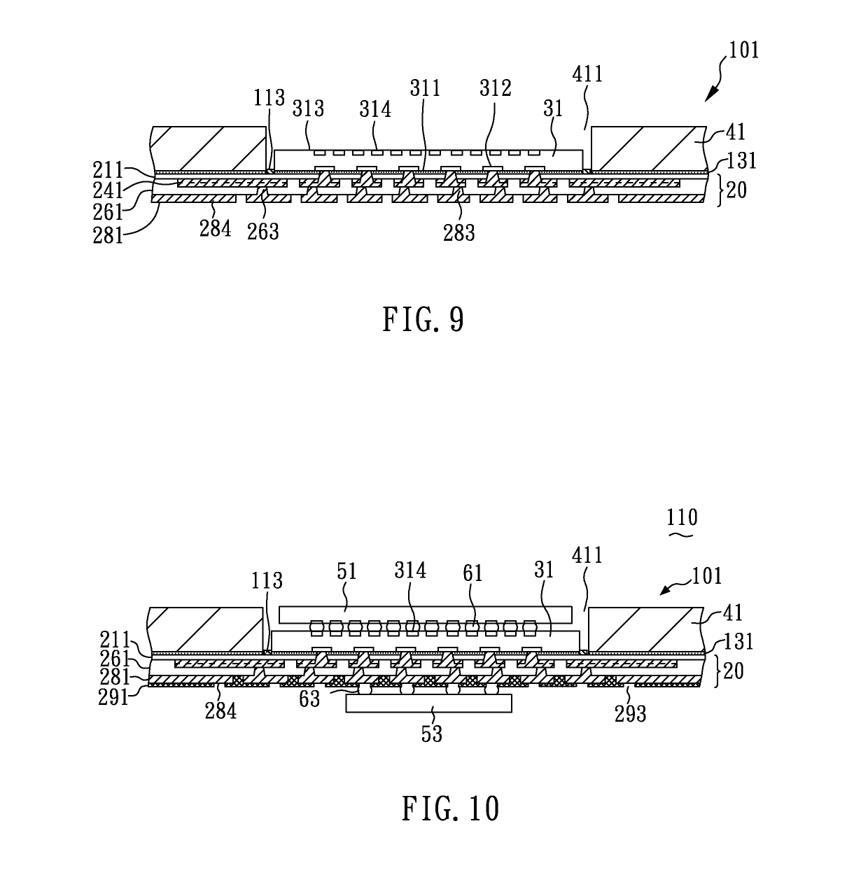

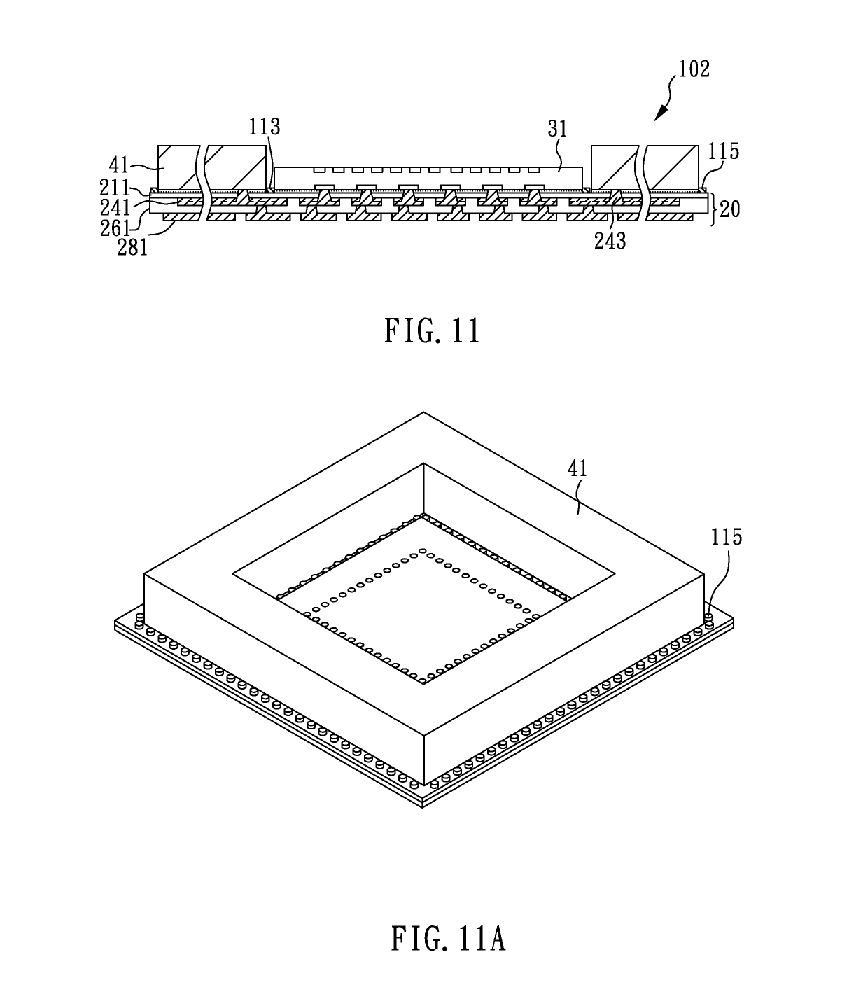

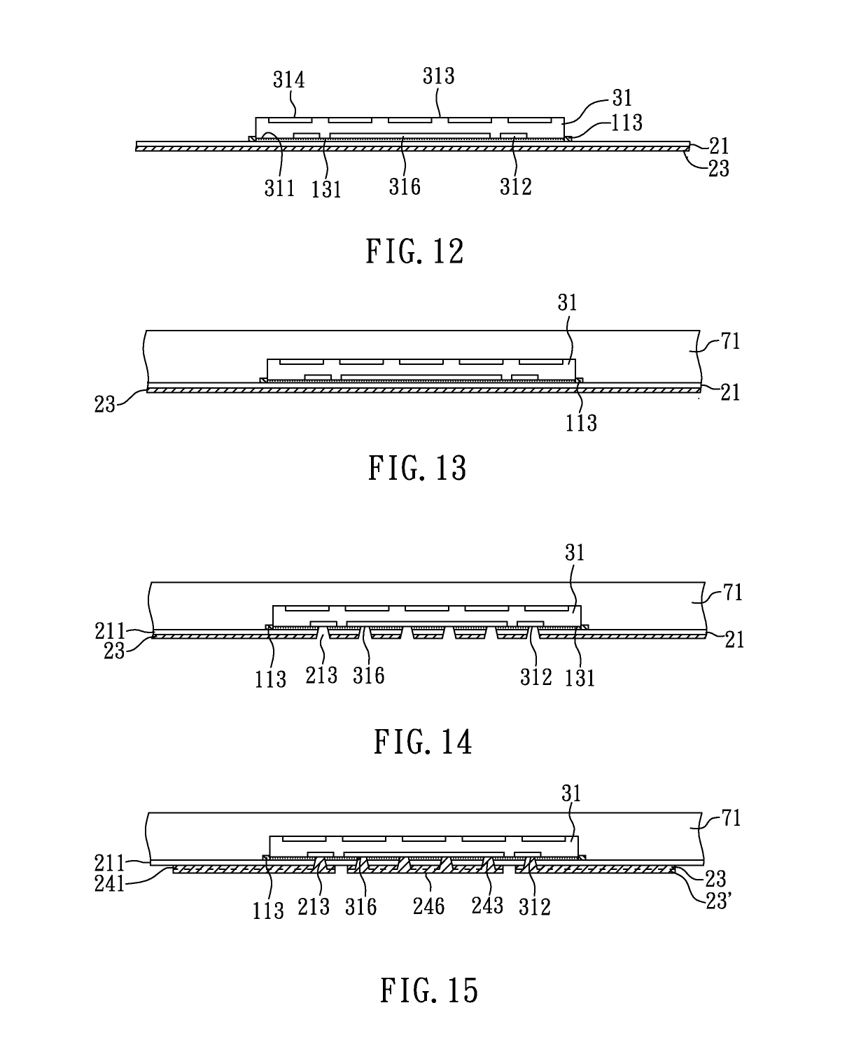

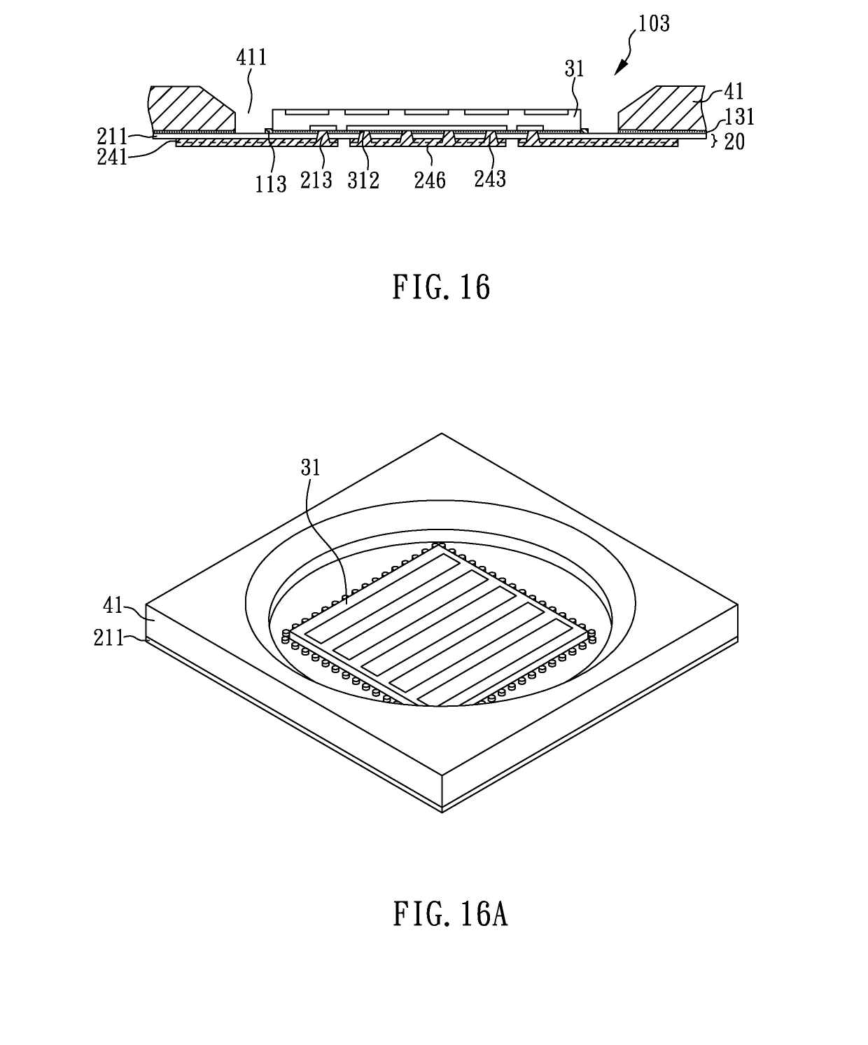

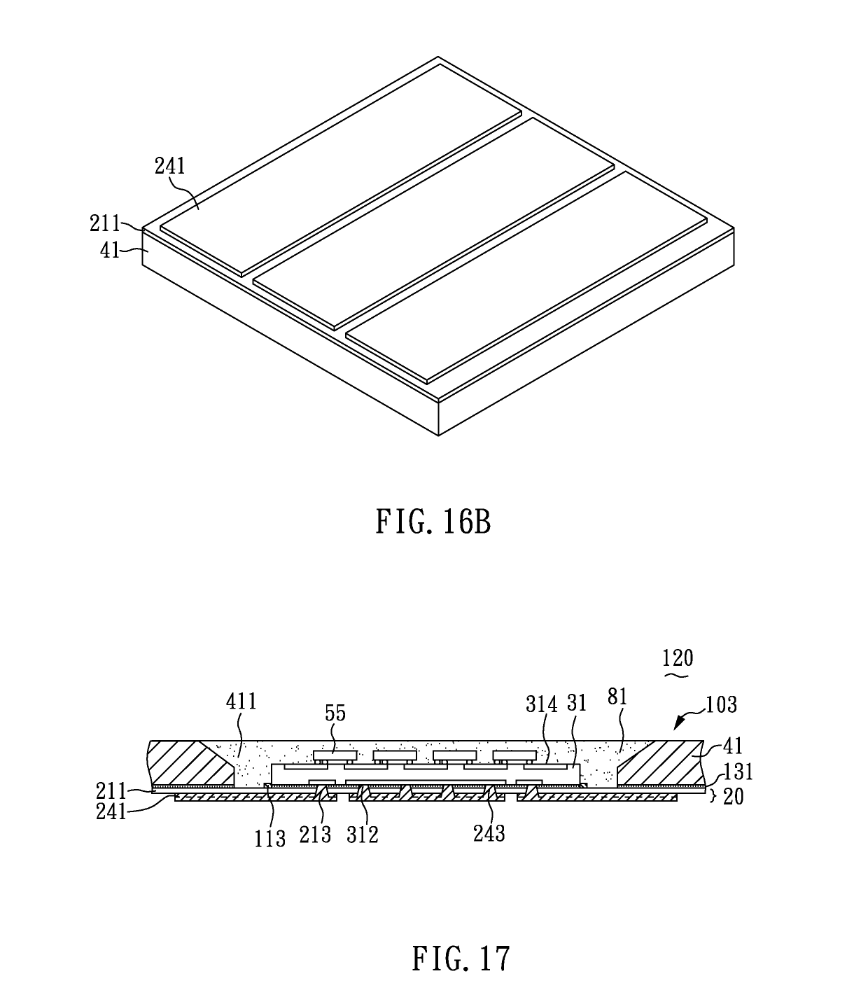

FIG. 2A′ is a top view corresponding to FIG. 2′;

FIGS. 2B-2E are top views of various stopper patterns that can be practiced in the present invention;

FIGS. 3 and 3A are cross-sectional and top views, respectively, of the structure with an interposer mounted thereon in accordance with an embodiment of the present invention;

FIGS. 4 and 4A are cross-sectional and top views, respectively, of the structure with a stiffener mounted thereon in accordance with an embodiment of the present invention;

FIGS. 5-9 are cross-sectional views showing a method of making a hybrid wiring board that includes an interposer, a stopper, a stiffener and a build-up circuitry electrically connected to the interposer in accordance with an embodiment of the present invention;

FIG. 10 is a cross-sectional view showing a three-dimensional assembly that includes semiconductor devices attached to both sides of a hybrid wiring board in accordance with an embodiment of the present invention;

FIGS. 11 and 11A are cross-sectional and top views, respectively, of a hybrid wiring board that includes an interposer, a stopper, a placement guide, a stiffener and a build-up circuitry electrically connected to the interposer in accordance with another embodiment of the present invention;

FIGS. 12-16 are cross-sectional views showing a method of making yet another hybrid wiring board for an LED module in accordance with yet another embodiment of the present invention;

FIG. 16A is a top view corresponding to FIG. 16;

FIG. 16B is a bottom view corresponding to FIG. 16; and

FIG. 17 is a cross-sectional view showing an LED module that includes a hybrid wiring board, LED chips and a fluorescent material in accordance with another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

FIGS. 1 and 2 are cross-sectional views showing a method of forming a stopper on a dielectric layer in accordance with an embodiment of the present invention, and FIG. 2A is a top view corresponding to FIG. 2.

FIG. 1 is a cross-sectional view of a laminate substrate that includes metal layer 11, dielectric layer 21 and support plate 23. Metal layer 11 is illustrated as a copper layer with a thickness of 35 microns. However, metal layer 11 can also be made of other various metal materials and is not limited to a copper layer. Besides, metal layer 11 can be deposited on dielectric layer 21 by numerous techniques including lamination, electroplating, electroless plating, evaporating, sputtering, and their combinations as a single layer or multiple layers, and preferably has a thickness in a range of 10 to 200 microns.

Dielectric layer 21 typically is made of epoxy resin, glass-epoxy, polyimide and the like and has a thickness of 50 microns. In this embodiment, dielectric layer 21 is sandwiched between metal layer 11 and support plate 23. However, support plate 23 may be omitted in some embodiments. Support plate 23 typically is made of copper, but copper alloys or other materials are also doable. The thickness of support plate 23 can range from 25 to 1000 microns, and preferably ranges from 35 to 100 microns in consideration of process and cost. In this embodiment, support plate 23 is illustrated as a copper plate with a thickness of 35 microns.

FIGS. 2 and 2A are cross-sectional and top views, respectively, of the structure with stopper 113 formed on dielectric layer 21. Stopper 113 can be formed by removing selected portions of metal layer 11 using photolithography and wet etching. In this illustration, stopper 113 consists of plural metal posts in a rectangular frame array and conforms to four sides of an interposer subsequently disposed on dielectric layer 21. However, stopper patterns are not limited thereto and can be other various patterns against undesirable movement of the subsequently disposed interposer.

FIGS. 1′ and 2′ are cross-sectional views showing an alternative method of forming a stopper on a dielectric layer, and FIG. 2A′ is a top view corresponding to FIG. 2′.

FIG. 1′ is a cross-sectional view of a laminate substrate with a set of cavities 111. The laminate substrate includes metal layer 11, dielectric layer 21 and support plate 23 as above mentioned, and cavities 111 are formed by removing selected portions of metal layer 11.

FIGS. 2′ and 2A′ are cross-sectional and top views, respectively, of the structure with stopper 113 formed on dielectric layer 21. Stopper 113 can be formed by dispensing or printing a photosensitive plastic material (e.g., epoxy, polyimide, etc.) or non-photosensitive material into cavities 111, followed by removing overall metal layer 11. Herein, stopper 113 is illustrated as an array of plural resin posts and conforms to two diagonal corners of a subsequently disposed interposer.

FIGS. 2B-2E are top views of other various stopper patterns for reference. For instance, stopper 113 may consist of a continuous or discontinuous strip and conform to four sides (as shown FIGS. 2B and 2C), two diagonal corners or four corners (as shown in FIGS. 2D and 2E) of a subsequently disposed interposer.

FIGS. 3-9 are cross-sectional views showing a method of making a hybrid wiring board that includes an interposer, a stopper, a stiffener and build-up circuitry in accordance with an embodiment of the present invention.

As shown in FIG. 9, hybrid wiring board 101 includes interposer 31, stopper 113, stiffener 41 and build-up circuitry 20. Interposer 31 includes first surface 311, second surface 313 opposite to first surface 311, first contact pads 312 at first surface 311, second contact pads 314 at second surface 313, and through vias (not shown in the figures) that electrically connect first contact pads 312 and second contact pads 314. Interposer 31 can be a silicon interposer, a glass interposer or a ceramic interposer that contains a pattern of traces that fan out from a fine pitch at second contact pads 314 to a coarse pitch at first contact pads 312. Build-up circuitry 20 is electrically connected to interposer 31 and includes first insulating layer 211, first conductive traces 241, second insulating layer 261 and second conductive traces 281 which include interconnect pads 284. Stopper 113 extends from first insulating layer 211 of build-up circuitry 20 in the upward direction and is in close proximity to peripheral edges of interposer 31. Stopper 113 as well as interposer 31 are aligned with and extend into aperture 411 of stiffener 41.

FIGS. 3 and 3A are cross-sectional and top views, respectively, of the structure with interposer 31 mounted on dielectric layer 21 using adhesive 131. Interposer 31 includes first surface 311, second surface 313 opposite to first surface 311, first contact pads 312 at first surface 311, second contact pads 314 at second surface 313, and through vias (not shown in the figures) that electrically connect the first contact pads 312 and the second contact pads 314. Interposer 31 can be a silicon interposer, a glass interposer or a ceramic interposer that contains a pattern of traces that fan out from a fine pitch at second contact pads 314 to a coarse pitch at first contact pads 312.

Stopper 113 can serve as a placement guide for interposer 31, and thus interposer 31 is precisely placed at a predetermined location with its first surface 311 facing dielectric layer 21. Stopper 113 extends from dielectric layer 21 beyond first surface 311 of interposer 31 in the upward direction and is laterally aligned with and laterally extends beyond four sides of interposer 31 in the lateral directions. As stopper 113 is in close proximity to and conforms to four lateral surfaces of interposer 31 in lateral directions and adhesive 131 under interposer 31 is lower than stopper 113, any undesirable movement of interposer 31 due to adhesive curing can be avoided. Preferably, a gap in between interposer 31 and stopper 113 is in a range of about 0.001 to 1 mm.

FIGS. 4 and 4A are cross-sectional and top views, respectively, of the structure with stiffener 41 mounted on dielectric layer 21 using adhesive 131. Interposer 31 and stopper 113 are aligned with and inserted into aperture 411 of stiffener 41 and stiffener 41 is mounted on dielectric layer 21 using adhesive 131. Aperture 411 is formed by laser cutting through stiffener 41 and can be formed with other techniques such as punching and mechanical drilling. Stiffener 41 is illustrated as a ceramic sheet with a thickness of about 0.6 mm, but also can be single layer or multi-layer laminate structures, such as a multi-layer circuit board, a glass sheet or a metal sheet.

Interposer 31 and the inner wall of aperture 411 are spaced from one another by stopper 113. Stopper 113 is in close proximity to and laterally aligned with four inner walls of aperture 411 and adhesive 131 under stiffener 41 is lower than stopper 113, and thus any undesirable movement of stiffener 41 also can be avoided before adhesive 131 is fully cured. Optionally, a bonding material (not shown in the figure) can be added between interposer 31 and stiffener 41 to enhance rigidity.

FIG. 5 is a cross-sectional view of the structure showing first via openings 213 formed through adhesive 131, dielectric layer 21 and support plate 23 to expose first contact pads 312. First via openings 213 may be formed by numerous techniques including laser drilling, plasma etching and photolithography. Laser drilling can be enhanced by a pulsed laser. Alternatively, a scanning laser beam with a metal mask can be used. For instance, copper can be etched first to create a metal window followed by laser. First via openings 213 typically have a diameter of 50 microns, and dielectric layer 21 is considered first insulating layer 211 of build-up circuitry.

Referring now to FIG. 6, first conductive traces 241 are formed on first dielectric layer 211 by depositing plated layer 23′ on support plate 23 and into first via openings 213 and then patterning support plate 23 and plated layer 23′ thereon. Alternatively, in some embodiments which apply a laminate substrate without support plate 23 or remove support plate 23 after the step illustrated in FIG. 4, the dielectric layer 21 can be directly metallized to form first conductive traces 241 after forming first via openings 213.

Plated layer 23′ can be deposited by numerous techniques including electroplating, electroless plating, evaporating, sputtering, and their combinations as a single layer or multiple layers. For instance, plated layer 23′ is deposited by first dipping the structure in an activator solution to render first insulating layer 211 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, support plate 23 and plated layer 23′ can be patterned to form first conductive traces 241 by numerous techniques including wet etching, electro-chemical etching, laser-assist etching, and their combinations with an etch mask (not shown) thereon that defines first conductive traces 241. Accordingly, first conductive traces 241 extend from first insulating layer 211 in the downward direction, extend laterally on first insulating layer 211 and extend into first via openings 213 in the upward direction to form first conductive vias 243 in electrical contact with first contact pads 312.

Support plate 23 and plated layer 23′ thereon are shown as a single layer for convenience of illustration. The boundary (shown in phantom) between the metal layers may be difficult or impossible to detect since copper is plated on copper. However, the boundary between plated layer 23′ and first insulating layer 211 is clear.

FIG. 7 is a cross-sectional view of the structure showing second insulating layer 261 disposed on first conductive traces 241 and first insulating layer 211. Second insulating layer 261 can be epoxy resin, glass-epoxy, polyimide and the like deposited by numerous techniques including film lamination, spin coating, roll coating, and spray-on deposition and typically has a thickness of 50 microns. Preferably, first insulating layer 211 and second insulating layer 261 are the same material.

FIG. 8 is a cross-sectional view of the structure showing second via openings 263 formed through second insulating layer 261 to expose selected portions of first conductive traces 241. Like first via openings 213, second via openings 263 can be formed by numerous techniques including laser drilling, plasma etching and photolithography and typically have a diameter of 50 microns. Preferably, first via openings 213 and second via openings 263 have the same size.

Referring now to FIG. 9, second conductive traces 281 are formed on second insulating layer 261. Second conductive traces 281 extend from second insulating layer 261 in the downward direction, extend laterally on second insulating layer 261 and extend into second via openings 263 in the upward direction to form second conductive vias 283 in electrical contact with first conductive traces 241.

Second conductive traces 281 can be deposited as a conductive layer by numerous techniques including electrolytic plating, electroless plating, sputtering, and their combinations and then patterned by numerous techniques including wet etching, electro-chemical etching, laser-assist etching, and their combinations with an etch mask (not shown) thereon that defines second conductive traces 281. Preferably, first conductive traces 241 and second conductive traces 281 are the same material with the same thickness.

Accordingly, as shown in FIG. 9, hybrid wiring board 101 is accomplished and includes interposer 31, stopper 113, stiffener 41 and build-up circuitry 20. In this illustration, build-up circuitry 20 includes first insulating layer 211, first conductive traces 241, second insulating layer 261 and second conductive traces 281.

Interposer 31 and stiffener 41 are attached onto first insulating layer 211 through adhesive 131 that contacts and is sandwiched between interposer 31 and first insulating layer 211 and between stiffener 41 and first insulating layer 211, and are spaced from each other by stopper 113 between interposer 31 and stiffener 41. Stopper 113 extends from first insulating layer 211 of build-up circuitry 20 in the upward direction and is in close proximity to peripheral edges of interposer 31 and inner walls of aperture 411. Adhesive 131 contacts and is coplanar with stopper 113 in the downward direction and is lower than stopper 113 in the upward direction. First conductive traces 241 of build-up circuitry 20 directly contact first contact pads 312 of interposer 31, and thus the electrical connection between interposer 31 and build-up circuitry 20 is devoid of solder.

FIG. 10 is a cross-sectional view of three dimensional assembly 110 with chips 51, 53 attached on both sides of hybrid wiring board 101. One chip 51 is electrically connected to second contact pads 314 of interposer 31 via solder bumps 61, while another chip 53 is aligned with the placement location of interposer 31 and electrically coupled to build-up circuitry 20 via solder bumps 63 on interconnect pads 284 exposed from opening 293 of solder mask material 291. Accordingly, chips 51, 53 can be electrically connected to one another through interposer 31, build-up circuitry 20 and solder bumps 61, 63. Moreover, the rest of interconnect pads 284 exposed from opening 293 of solder mask material 291 can accommodate a conductive joint, such as solder bump, solder ball, pin, and the like, for electrical communication and mechanical attachment with another assembly or external components. The solder mask openings 293 may be formed by numerous techniques including photolithography, laser drilling and plasma etching.

### Embodiment 2

FIGS. 11 and 11A are cross-sectional and top views, respectively, of hybrid wiring board 102 with placement guide 115 in close proximity to the outer peripheral edges of stiffener 41 and additional first conductive vias 243 in direct contact with stiffener 41 in accordance with another embodiment of the present invention.

In this embodiment, hybrid wiring board 102 is manufactured in a manner similar to that illustrated in Embodiment 1, except that placement guide 115 is simultaneously formed during stopper 113 formation by removing selected portions of metal layer 11 to accurately confine the placement location of stiffener 41 and additional first conductive vias 243 are formed in direct contact with stiffener 41. Placement guide 115 extends from first insulating layer 211 beyond the attached surface of stiffener 41 in the upward direction and is laterally aligned with and laterally extends beyond four outer lateral surfaces of stiffener 41 in the lateral directions. Placement guide 115 is illustrated as plural metal posts and conforms to four outer sides of stiffener 41 in lateral directions. However, placement guide 115 is not limited to the illustrated pattern and can be designed in other various patterns. As placement guide 115 is in close proximity to and conforms to four outer lateral surfaces of stiffener 41 in lateral directions and adhesive 131 under stiffener 41 is lower than placement guide 115, any undesirable movement of stiffener 41 due to adhesive curing can be avoided. Preferably, a gap in between the outer peripheral edges of stiffener 41 and placement guide 115 is in a range of about 0.001 to 1 mm.

### Embodiment 3

FIGS. 12-16 are cross-sectional views showing a method of making a hybrid wiring board for an LED module in accordance with yet another embodiment of the present invention.

For purposes of brevity, any description in Embodiment 1 is incorporated herein insofar as the same is applicable, and the same description need not be repeated.

FIG. 12 is a cross-sectional view of the structure which is manufactured by the steps shown in FIGS. 1-3. In this embodiment, interposer 31 further includes thermal pad 316 on first surface 311 in addition to first contact pads 312, second contact pads 314 and through vias (not shown in the figures).

FIG. 13 is a cross-sectional view of the structure in which protective film 71 is attached thereto and support plate 23 is thinned. Protective film 71 covers interposer 31, stopper 113 and dielectric layer 21 in the upward direction. After protective film 71 is provided, support plate 23 is thinned from 35 microns to about 15 microns.

FIG. 14 is a cross-sectional view of the structure showing first via openings 213 formed through adhesive 131, dielectric layer 21 and support plate 23. First via openings 213 are aligned with and expose first contact pads 312 and thermal pad 316 of interposer 31, and dielectric layer 21 is considered first insulating layer 211 of build-up circuitry.

FIG. 15 is a cross-sectional view of the structure showing first conductive traces 241 with thermal paddle 246 formed on first dielectric layer 211 by depositing and patterning metal. First conductive traces 241 with thermal paddle 246 are formed by depositing plated layer 23′ on thinned support plate 23 and into first via openings 213 and then patterning support plate 23 and plated layer 23′ thereon. Plated layer 23′ covers and extends from thinned support plate 23 in the downward direction and extends into first via openings 213 in the upward direction to form first conductive vias 243 in contact with first contact pads 312 and thermal pad 316, thereby providing thermally conductive pathway and signal routing for interposer 31.

Support plate 23 and plated layer 23′ thereon are shown as a single layer for convenience of illustration. The boundary (shown in phantom) between the metal layers may be difficult or impossible to detect since copper is plated on copper. However, the boundary between plated layer 23′ and first insulating layer 211 is clear.

FIGS. 16, 16A and 16B are cross-sectional, top and bottom views, respectively, of the structure provided with stiffener 41. Stiffener 41 is mounted on first insulating layer 211 using adhesive 131 after removing protective film 71 so as to provide mechanical support and define the area for fluorescent material. Interposer 31 and stopper 113 are aligned with and exposed from aperture 411 of stiffener 41.

Accordingly, as shown in FIG. 16, hybrid wiring board 103 is accomplished and includes interposer 31, stopper 113, stiffener 41 and build-up circuitry 20. In this illustration, build-up circuitry 20 includes first dielectric layer 211 and first conductive traces 241 with thermal paddle 246.

FIG. 17 is a cross-sectional view of LED module 120 with hybrid wiring board 103, LED chips 55 and fluorescent material 81. LED chips 55 are mounted on second contact pads 314 of interposer 31, and electrically connected to build-up circuitry. Fluorescent material 81 fills aperture 411 of stiffener 41 and covers LED chips 55, interposer 31 and stopper 113.

The three dimensional semiconductor assemblies and wiring boards described above are merely exemplary. Numerous other embodiments are contemplated. In addition, the embodiments described above can be mixed-and-matched with one another and with other embodiments depending on design and reliability considerations. For instance, the stiffener can include ceramic material, metal material or epoxy-based laminate, and can have embedded single-level conductive traces or multi-level conductive traces. The stiffener can include multiple apertures to accommodate additional interposers, passive components or other electronic devices and the build-up circuitry can include additional conductive traces to accommodate additional interposers, passive components or other electronic devices. For instance, the stiffener can include an aperture for placing an interposer therein and multiple apertures for placing passive components therein.

As shown in the above embodiments, a semiconductor device can share or not share the interposer with other semiconductor devices. For instance, a single semiconductor device can be mounted on the interposer. Alternatively, numerous semiconductor devices can be mounted on the interposer. For instance, four small chips in a 2×2 array can be attached to the interposer and the interposer can include additional contact pads to receive and route additional chip pads. This may be more cost effective than providing an interposer for each chip. Likewise, an aperture of the stiffener can include multiple sets of stoppers to accommodate multiple additional interposers therein and the build-up circuitry can include additional conductive traces to accommodate additional interposers.

The semiconductor device can be a packaged or unpackaged chip. Furthermore, the semiconductor device can be a bare chip, or a wafer level packaged die, etc. A semiconductor device can be mechanically and electrically connected to the interposer using a wide variety of connection media including gold or solder bumps. The stopper can be customized for the interposer. For instance, the stopper can have a pattern that defines a square or rectangular area with the same or similar topography as the interposer. External heat dissipation element such as heat spreader or heat sink can be attached to the semiconductor device by thermally conductive adhesive or soldering material. The external heat dissipation element can also be attached to the stiffener to extend the contact area and enhance the efficiency of the dissipation pathway for the semiconductor device.

The term “adjacent” refers to elements that are integral (single-piece) or in contact (not spaced or separated from) with one another. For instance, the first conductive trace is adjacent to the first contact pad but not the second contact pad.

The term “overlap” refers to above and extending within a periphery of an underlying element. Overlap includes extending inside and outside the periphery or residing within the periphery. For instance, in the position that the second contact pads of the interposer faces the upward direction, the stiffener overlaps the dielectric layer since an imaginary vertical line intersects the stiffener and the dielectric layer, regardless of whether another element such as the adhesive is between the stiffener and the dielectric layer and is intersected by the line, and regardless of whether another imaginary vertical line intersects the dielectric layer but not the stiffener (within the aperture of the stiffener). Likewise, the adhesive overlaps the dielectric layer, the stiffener overlaps the adhesive and the adhesive is overlapped by the stiffener. Moreover, overlap is synonymous with over and overlapped by is synonymous with under or beneath.

The term “contact” refers to direct contact. For instance, the conductive trace contacts the first contact pad but not the second contact pad.

The term “cover” refers to complete coverage in a vertical and/or lateral direction. For instance, in the position that the second contact pads of the interposer faces the upward direction, the build-up circuitry covers the interposer in the downward direction but the interposer does not cover the build-up circuitry in the upward direction.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening” and “aperture” refer to a through hole and are synonymous. For instance, in the position that the second contact pads of the interposer faces the upward direction, the interposer is exposed by the stiffener in the upward direction when it is inserted into the aperture in the stiffener.

The term “inserted” refers to relative motion between elements. For instance, the interposer is inserted into the aperture regardless of whether the stiffener is stationary and the interposer moves towards the stiffener, the interposer is stationary and the stiffener moves towards the interposer or the interposer and the stiffener both approach the other. Furthermore, the interposer is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the interposer since an imaginary horizontal line intersects the stopper and the interposer, regardless of whether another element is between the stopper and the interposer and is intersected by the line, and regardless of whether another imaginary horizontal line intersects the interposer but not the stopper or intersects the stopper but not the interposer. Likewise, the first via opening is aligned with the first contact pads of the interposer, and the interposer and the stopper are aligned with the aperture.

The phrase “in close proximity to” refers to a gap between elements not being wider than the maximum acceptable limit. As known in the art, when the gap between the interposer and the stopper is not narrow enough, the location error of the interposer due to the lateral displacement of the interposer within the gap may exceed the maximum acceptable error limit. Once the location error of the interposer goes beyond the maximum limit, it is impossible to align the contact pad with a laser beam, resulting in the electrical connection failure between the interposer and the build-up circuitry. According to the pad size of the interposer, those skilled in the art can ascertain the maximum acceptable limit for a gap between the interposer and the stopper through trial and error to prevent the electrical connection failure between the interposer and the build-up circuitry. Thereby, the description “the stopper is in close proximity to the peripheral edges of the interposer” means that the gap between the peripheral edges of the interposer and the stopper is narrow enough to prevent the location error of the interposer from exceeding the maximum acceptable error limit.

The phrase “mounted on” includes contact and non-contact with a single or multiple support element(s). For instance, the interposer is mounted on the dielectric layer regardless of whether it contacts the dielectric layer or is separated from the dielectric layer by an adhesive.

The phrase “electrical connection” or “electrically connects” or “electrically connected” refers to direct and indirect electrical connection. For instance, the first conductive trace provides an electrical connection between the interconnect pad and the first contact pad regardless of whether the first conductive trace is adjacent to the interconnect pad or electrically connected to the interconnect pad by the second conductive trace.

The term “above” refers to upward extension and includes adjacent and non-adjacent elements as well as overlapping and non-overlapping elements. For instance, in the position that the second contact pads of the interposer faces the upward direction, the stopper extends above, is adjacent to and protrudes from the dielectric layer.

The term “below” refers to downward extension and includes adjacent and non-adjacent elements as well as overlapping and non-overlapping elements. For instance, in the position that the second contact pads of the interposer faces the upward direction, the build-up circuitry extends below, is adjacent to and protrudes from the adhesive in the downward direction. Likewise, the build-up circuitry extends below the stiffener and the interposer even though it is not adjacent to the stiffener and the interposer.

The “first vertical direction” and “second vertical direction” do not depend on the orientation of the wiring board, as will be readily apparent to those skilled in the art. For instance, the first contact pads of the interposer faces the first vertical direction and the second contact pads of the interposer faces the second vertical direction regardless of whether the wiring board is inverted. Likewise, the stopper is “laterally” aligned with the interposer in a lateral plane regardless of whether the wiring board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the second contact pads of the interposer faces the upward direction, and the first vertical direction is the upward direction and the second vertical direction is the downward direction in the position that the second contact pads of the interposer faces the downward direction.

The wiring board and the semiconductor assembly using the same according to the present invention have numerous advantages. The wiring board made by this method and the semiconductor assembly using the same are reliable, inexpensive and well-suited for high volume manufacture. The stiffener provides the mechanical support, dimensional stability and controls the overall flatness and the thermal expansion of the build-up circuitry such that the interposer can be securely connected to the build-up circuitry under thermal cycling even though the coefficient of thermal expansion (CTE) between them may be different. The direct electrical connection without solder between the interposer and the build-up circuitry is advantageous to high I/O and high performance. Particularly, the stopper can accurately confine the placement location of the interposer and avoid the electrical connection failure between the interposer and the build-up circuitry resulted from the lateral displacement of the interposer, thereby improving the manufacturing yield greatly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A method of making a hybrid wiring board with built-in stopper and interposer, comprising:
forming a stopper on a dielectric layer;
mounting an interposer on the dielectric layer using the stopper as a placement guide for the interposer that includes a first contact pad and a second contact pad on two opposite surfaces thereof, wherein the first contact pad faces a first vertical direction and is attached to the dielectric layer, the second contact pad faces a second vertical direction opposite the first vertical direction, and the stopper is located in close proximity to and laterally aligned with and laterally extends beyond peripheral edges of the interposer in lateral directions orthogonal to the vertical directions;
attaching a stiffener to the dielectric layer, including aligning the interposer and the stopper within an aperture of the stiffener; and
forming a build-up circuitry that covers the stopper, the interposer and the stiffener in the first vertical direction and includes a first conductive via that directly contacts the first contact pad of the interposer to provide an electrical connection between the interposer and the build-up circuitry.

2. The method of claim 1, wherein the electrical connection between the interposer and the build-up circuitry is devoid of solder.

3. The method of claim 1, wherein forming the stopper on the dielectric layer includes:
providing a laminate substrate that includes a metal layer and the dielectric layer; and then
removing a selected portion of the metal layer to form the stopper.

4. The method of claim 1, forming the stopper on the dielectric layer includes:
providing a laminate substrate that includes a metal layer and the dielectric layer; then
removing a selected portion of the metal layer to form a recessed portion; then
depositing a plastic material into the recessed portion; and then
removing a remaining portion of the metal layer.

5. The method of claim 1, wherein interposer is attached to the dielectric layer using an adhesive that contacts and is sandwiched between the interposer and the dielectric layer.

6. The method of claim 5, wherein the adhesive contacts and is coplanar with the stopper in the first vertical direction and is lower than the stopper in the second vertical direction.

7. The method of claim 1, wherein forming the build-up circuitry includes:
providing a first insulating layer that includes the dielectric layer and covers the stopper, the interposer and the stiffener in the first vertical direction; then
forming a first via opening that extends through the first insulating layer and is aligned with the first contact pad of the interposer; and then forming a first conductive trace that extends from the first insulating layer in the first vertical direction and extends laterally on the first insulating layer and extends through the first via opening in the second vertical direction to form the first conductive via in direct contact with the first contact pad of the interposer.

8. The method of claim 7, wherein forming the build-up circuitry includes:
forming an additional first via opening that extends through the first insulating layer and is aligned with the stiffener; and then
forming the first conductive trace that extends through the additional first via opening in the second vertical direction to form an additional first conductive via in direct contact with the stiffener.

9. The method of claim 1, wherein the stopper include a continuous or discontinuous strip or an array of posts.

10. The method of claim 1, wherein a gap in between the interposer and the stopper is in a range of 0.001 to 1 mm.

11. The method of claim 1, wherein the stopper has a height in a range of 10 to 200 microns.

12. The method of claim 1, wherein the interposer has a through via that electrically connects the first contact pad and the second contact pad.

13. A method of making a hybrid wiring board with built-in stopper and interposer, comprising:
forming a stopper on a dielectric layer;
mounting an interposer on the dielectric layer using the stopper as a placement guide for the interposer that includes a first contact pad and a second contact pad on two opposite surfaces thereof, wherein the first contact pad faces a first vertical direction and is attached to the dielectric layer, the second contact pad faces a second vertical direction opposite the first vertical direction, and the stopper is located in close proximity to and laterally aligned with and laterally extends beyond peripheral edges of the interposer in lateral directions orthogonal to the vertical directions;
providing a protective film that covers the interposer, the stopper and the dielectric layer in the second vertical direction;
forming a build-up circuitry that covers the stopper, the interposer and the protective film in the first vertical direction and includes a first conductive via that directly contacts the first contact pad of the interposer to provide an electrical connection between the interposer and the build-up circuitry;
removing the protective film; and
attaching a stiffener to the dielectric layer, including aligning the interposer and the stopper within an aperture of the stiffener.
